(19) United States
(12) Patent Application Publication
(10) Pub. No.: US 2024/0213301 A1
(43) Pub. Date: Jun. 27, 2024

(54) THIN FILM CAPACITOR (TFC) ARCHITECTURES FOR PACKAGE SUBSTRATES

(71) Applicant: Intel Corporation, Santa Clara, CA (US)

(72) Inventors: Darko GRUJICIC, Chandler, AZ (US); Thomas L. SOUNART, Chandler, AZ (US); Benjamin DUONG, Phoenix, AZ (US); Kristof DARMAWIKARTA, Chandler, AZ (US); Shayan KAVIANI, Phoenix, AZ (US); Suddhasattwa NAD, Chandler, AZ (US); Mahdi MOHAMMADIGHALENI, Phoenix, AZ (US); Marcel WALL, Phoenix, AZ (US); Rengarajan SHANMUGAM, Tempe, AZ (US)

(21) Appl. No.: 18/089,471

(22) Filed: Dec. 27, 2022

(51) Int. Cl. H01G 4/33

(52) U.S. Cl. CPC H01L 28/40; H01G 4/33

(57) ABSTRACT

Embodiments disclosed herein include a package core. In an embodiment, the package core comprises a core substrate that includes glass. In an embodiment, a cavity is provided into the core substrate. In an embodiment, a capacitor is lining sidewalls of the cavity, and the capacitor comprises a first layer, a dielectric layer over the first layer, and a second layer over the dielectric layer.

### TECHNICAL FIELD

Embodiments of the present disclosure relate to electronic packages, and more particularly to package substrates with thin film capacitor (TFC) architectures.

### BACKGROUND

Capacitors are energy storage components used in the power delivery network for semiconductor packaging applications. They can be used, for example, as I/O voltage regulators to suppress noise during switching, or for decoupling. High frequency applications require capacitors whose performance will not degrade at higher frequencies. Existing solutions, like land-side ceramic capacitors or die-side ceramic capacitors, cannot meet these requirements because of breakdown concerns at high voltages. Also, such capacitors are relatively far from the computing die.

One solution is to use on-die metal insulator metal (MIM) capacitors. MIM capacitors have the capacity density required for such applications, but suffer from leakage due to the thin dielectric films that are used. As such, MIM capacitors are limited to low voltage applications. Accordingly, there is no existing solution that can operate at high frequency and high voltages.

### BRIEF DESCRIPTION OF THE DRAWINGS

FIG. 1 is a cross-sectional illustration of a core with an integrated thin film capacitor (TFC), in accordance with an embodiment.

FIGS. 2A-2F are cross-sectional illustrations of a process for forming a TFC on a core that comprises glass, in accordance with an embodiment.

FIG. 3 is a cross-sectional illustration of a package substrate with an integrated TFC, in accordance with an embodiment.

FIGS. 4A-4E are cross-sectional illustration of a process for forming a TFC in a package substrate, in accordance with an embodiment.

FIG. 5 is a cross-sectional illustration of a package substrate with a TFC that is provided over a photoimageable dielectric (PID), in accordance with an embodiment.

FIGS. 6A-6E are cross-sectional illustrations of a process for forming a TFC over a PID, in accordance with an embodiment.

FIG. 7 is a cross-sectional illustration of an electronic system with a glass core that comprises a TFC, in accordance with an embodiment.

FIG. 8 is a schematic of a computing device built in accordance with an embodiment.

### EMBODIMENTS OF THE PRESENT DISCLOSURE

Described herein are package substrates with thin film capacitor (TFC) architectures, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing capacitor structures for power delivery are currently limited. Die-side and land-side ceramic capacitors are limited to low frequencies and have a relatively large distance to the computing dies. Metal-insulator-metal (MIM) capacitors are on the computing die, but are often limited to low voltage applications, due to low breakdown levels. Accordingly, there is not a capacitor structure that enables both high frequency and high voltage applications, while still being relatively close to the compute dies.

Accordingly, embodiments disclosed herein include thin film capacitor (TFC) architectures that are integrated into the package substrate. In one embodiment, the TFC capacitor is integrated into the core of the package substrate. In other embodiments, the TFC is integrated into the buildup layers over the core. In certain embodiments, the capacitor structures are formed in a corrugated architecture. For example, vias into the core or in buildup layers can be used to form more surface area to increase the capacitance of the TFC within a small footprint. In other embodiments a scaffolding (e.g., comprising a photoimageable dielectric (PID)) is used in order to increase the capacitance density of the TFC.

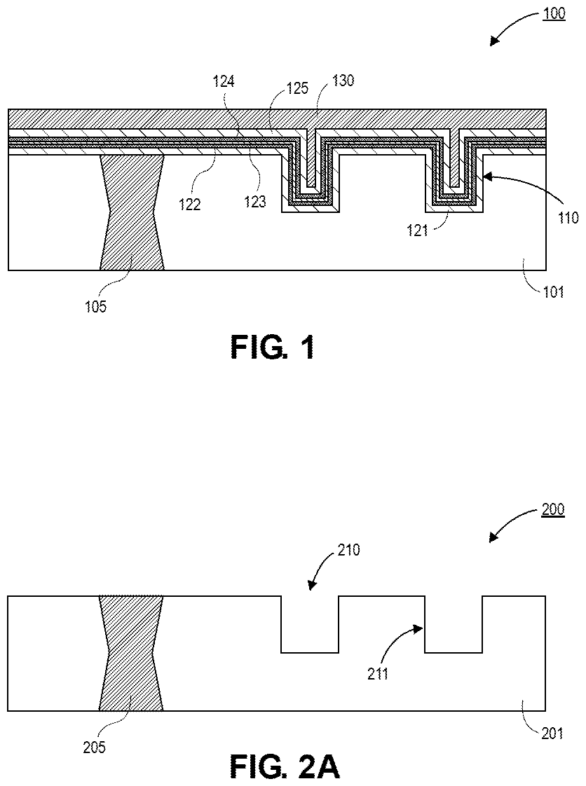

Referring now to FIG. 1, a cross-sectional illustration of a package substrate 100 at a stage of manufacture is shown, in accordance with an embodiment. In an embodiment, the package substrate 100 comprises a core 101. The core 101 may be a glass core 101. That is, the core 101 may comprise substantially all glass. The glass may be any suitable glass formulation, such as a fused silica glass, a borosilicate glass, or the like. The core 101 may have a thickness that is between approximately 50 μm and approximately 1,000 μm. Though, thinner or thicker cores 101 may be used in other embodiments. As used herein, “approximately” may refer to a range that is within ten percent of the stated value. For example, approximately 1,000 μm may refer to a range between 900 μm and 1,100 μm.

In an embodiment, the core 101 may be a glass formulation that is compatible with laser assisted patterning processes. Laser assisted patterning includes exposing the glass to a laser. The laser exposure alters a microstructure and/or phase of the glass compared to the unexposed regions. The exposed regions are rendered more susceptible to an etching chemistry. In this way, the laser exposed regions can be selectively removed in order to form via openings, trenches, holes, and the like. In some embodiments, the laser assisted patterning process may result in the formation of cavities with sloped sidewalls. In the case of a dual sided patterning (i.e., exposing both the top and bottom of the core 101 to a laser) the cavities may have hourglass shaped cross-sections. As used herein, an hourglass shaped cross-section may include a shape that has a top and bottom that are wider than a middle of the shape.

In an embodiment, one or more conductive features may be embedded in the core 101. For example, a through glass via (TGV) 105 may be provided through a thickness of the core 101. The TGV 105 may have an hourglass shaped cross-section in some embodiments. Though, the TGV 105 may have substantially vertical sidewalls, or sidewalls with a single slope.

In an embodiment, the core 101 may also comprise one or more cavities 110. The cavities 110 extend into a top surface of the core 101. The cavities 110 may be formed with a laser assisted etching process, such as the one described in greater detail above. In an embodiment, the cavities may extend into the surface of the core 101, but not through a thickness of the core 101. For example, the cavities 110 in FIG. 1 extend approximately half-way through a thickness of the core 101. Though, shallower or deeper cavities 110 may be formed in some embodiments. The cavities 110 may be one dimensional (e.g., holes where a depth is greater than a width and a length), two dimensional (e.g., trenches where a depth is greater than a width, and the length is similar to or greater than the depth), or any other shape.

In an embodiment, a capacitor structure may be formed over the core 101 and the cavities 110. The presence of the cavities 110 increases the surface area of the capacitor structure without increasing a footprint of the capacitor structure. As such, higher capacitance densities are provided. Increases to the capacitance density can be obtained by increasing the number of cavities 110, providing cavities 110 with higher aspect ratios, or the like.

In an embodiment, the capacitor structure may include a first layer 121. The first layer 121 may include a seed layer and a thicker copper layer or any other suitable conductive material. A TFC stack is then provided over the first layer 121. The TFC stack may include a first workfunction metal 122, a dielectric 123, and a second workfunction metal 124. In an embodiment, the first workfunction metal 122 and the second workfunction metal 124 may be the same material. Though in other embodiments, the workfunction metals 122 and 124 may be different materials. In an embodiment, the workfunction metals 122 and 124 may comprise ruthenium, ruthenium and oxygen, and/or tungsten.

In an embodiment, the dielectric 123 may be a high dielectric constant material. For example, the dielectric constant of the dielectric 123 may be greater than the dielectric constant of silicon dioxide. Particularly, the dielectric 123 may comprise titanium and oxygen (e.g., TiO₂), hafnium and oxygen (e.g., HfO), and/or aluminum and oxygen (e.g., Al₂O₃). Though, any suitable high-k dielectric material may be used as the dielectric 123. In an embodiment, the dielectric 123 may have a thickness that is between approximately 1 nm and approximately 100 nm. Though thinner or thicker dielectrics 123 may be used in some embodiments.

In an embodiment, a second layer 125 may be provided over the TFC stack. The second layer 125 may include a seed layer and/or a metal layer. For example, a copper seed layer and a layer of copper may be provided in the second layer 125. In the illustrated embodiment, there is no seam between the seed layer and the metal layer. Though, a seam may be present in some embodiments. In an embodiment, a third layer 130 may be provided over the second layer 125. The third layer 130 may comprise copper or the like. In some embodiments, the third layer 130 may be the same material as the second layer 125. That is, there may not be a visible seam between the second layer 125 and the third layer 130.

In an embodiment, the TFC stack may be electrically coupled to one or more TGVs 105. Other portions of the TFC stack, the first layer 121, and the third layer 130 may be etched back to electrically isolate the TFC stack from neighboring structures. The third layer 130 may be coupled to an overlying compute die (not shown) through buildup layers that are provided over the core 101 after the formation of the TFC stack.

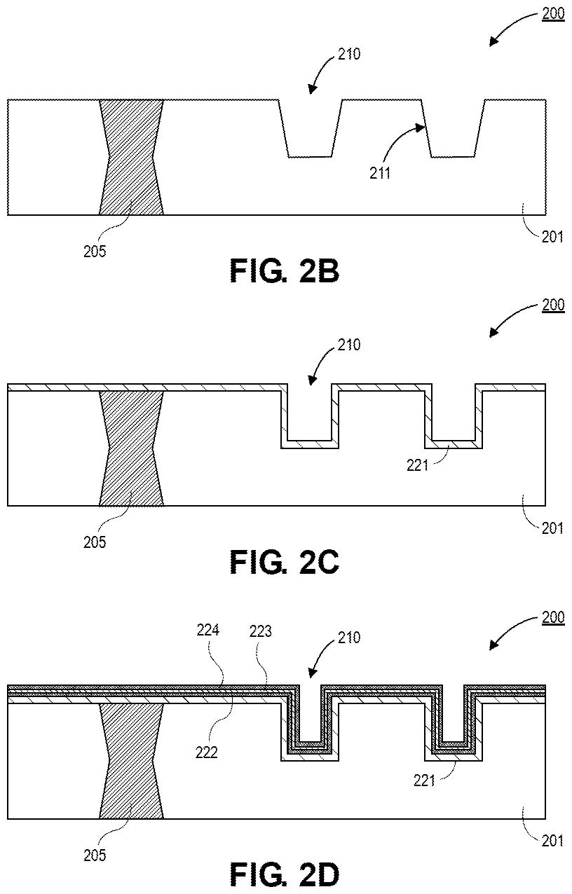

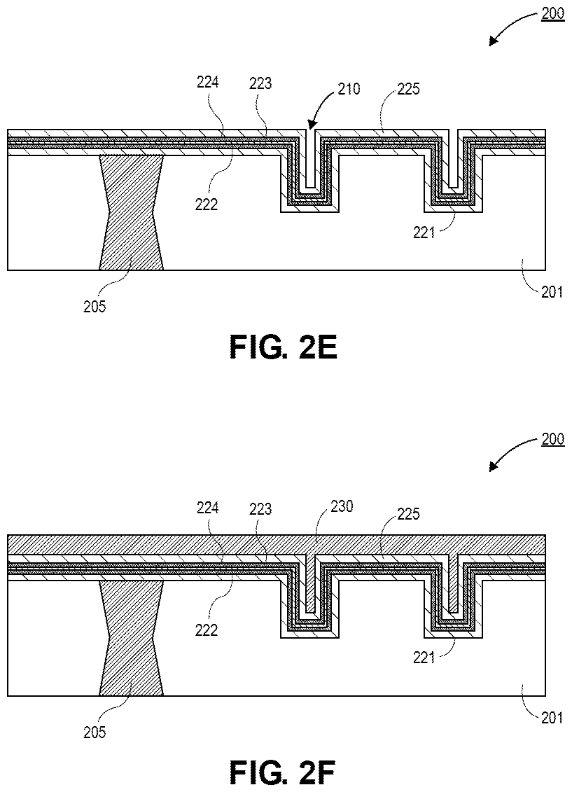

Referring now to FIGS. 2A-2F, a series of cross-sectional illustrations depicting a process for forming a package substrate 200 is shown, in accordance with an embodiment. In an embodiment, the package substrate 200 may be similar to the package substrate 100 described in greater detail above.

Referring now to FIG. 2A, a cross-sectional illustration of a package substrate 200 at a stage of manufacture is shown, in accordance with an embodiment. In an embodiment, the package substrate 200 comprises a core 201. The core 201 may be a glass core 201 or the like. That is, the core 201 may comprise substantially all glass in some embodiments. In an embodiment, a TGV 205 is provided through a thickness of the core 201. The TGV 205 may be an hourglass shaped feature in some embodiments. Though, embodiments are not limited to such shapes.

In an embodiment, one or more cavities 210 are formed into the top surface of the core 201. The cavities 210 may extend into, but not through, a thickness of the core 201. In the illustrated embodiment, the cavities 210 are provided approximately halfway through the thickness of the core 201. Though, deeper or shallower cavities 210 may be used in some embodiments. The cavities 210 may be high aspect ratio cavities 210 with a depth of the cavity 210 being larger than a width of the cavity 210. For example, a depth:width ratio of the cavity 210 may be approximately 2:1 or greater, 5:1 or greater, or 10:1 or greater.

In an embodiment, the cavities 210 may have sidewall surfaces 211. In the illustrated embodiment, the sidewall surfaces 211 are shown as being substantially vertical so that the plane of the sidewall surface 211 is substantially orthogonal to a plane of the top surface of the core 201. Though, it is to be appreciated that embodiments are not limited to such configurations. For example, in FIG. 2B the sidewall surfaces 211 are sloped. The slope of the sidewall surfaces 211 may result in a top of the cavity 210 that is wider than a bottom of the cavity 210. The shape of the cavity 210 may be referred to as being trapezoidal.

Referring now to FIG. 2C, a cross-sectional illustration of the package substrate 200 after a first layer 221 is deposited is shown, in accordance with an embodiment. In an embodiment, the first layer 221 may comprise a seed layer. The seed layer may comprise copper, platinum, titanium, or the like. After the deposition of the seed layer, a bulk metal layer (e.g., copper) can be plated to form the first layer 221. The bulk metal layer may be plated with electroplating processes or the like. The bulk metal layer may be conformally deposited.

Referring now to FIG. 2D, a cross-sectional illustration of the package substrate 200 after the TFC stack is formed is shown, in accordance with an embodiment. In an embodiment, the TFC stack may comprise a set of three layers. A first workfunction layer 222 may be provided over the first layer 221. The first workfunction layer 222 may comprise ruthenium, ruthenium oxide, or tungsten. In an embodiment, the first workfunction layer 222 may be deposited with an atomic layer deposition (ALD) process.

After the first workfunction layer 222, a dielectric layer 223 is deposited. The dielectric layer 223 may also be deposited with an ALD process. The dielectric layer 223 may be a high-k dielectric material. For example, the dielectric layer 223 may comprise titanium and oxygen, aluminum and oxygen, or hafnium and oxygen. The dielectric layer 223 may have a thickness that is between approximately 1 nm and approximately 100 nm. Though, thinner or thicker dielectric layers 223 may be used in some embodiments.

After the dielectric layer 223, a second workfunction layer 224 is deposited. The second workfunction layer 224 may be deposited with an ALD process or the like. In some embodiments, the second workfunction layer 224 may comprise the same material as the first workfunction layer 222. Though, in other embodiments, the second workfunction layer 224 may have a different material composition than the first workfunction layer 222.

As shown, the TFC stack comprising the first workfunction layer 222, the dielectric layer 223, and the second workfunction layer 224 may have a U-shaped cross-section. This is due to the TFC stack being deposited conformally over the sidewalls and the bottom surface of the cavities 210. The U-shaped TFC stack may include vertical arms along the sidewalls of the cavities 210 and a flat bottom surface over the bottom surface of the cavities 210. In the case of a tapered cavity 210 (similar to FIG. 2B), the arms may be sloped so that they are not vertical.

Referring now to FIG. 2E, a cross-sectional illustration of the package substrate 200 after a second layer 225 is deposited is shown, in accordance with an embodiment. In an embodiment, the second layer 225 may comprise a seed layer that includes one or more of copper, titanium, platinum, and the like. A bulk copper may be provided over the seed layer to complete the second layer 225 in some embodiments.

Referring now to FIG. 2F, a cross-sectional illustration of the package substrate 200 after a third layer 230 is formed over the second layer 225 is shown, in accordance with an embodiment. The third layer 225 may comprise copper or the like. In some embodiments, the third layer 230 may be plated with an electroplating process. In a particular embodiment, the third layer 230 is shown as a different shading than the second layer 225. Though, in some embodiments, the second layer 225 and the third layer 230 may be a single material composition, and there may not be a visible seam between the layers.

After formation of the third layer 225, the TFC stack, the first layer 221, the second layer 225, and the third layer 230 may be patterned (e.g., with a lithography and etching process). That is, the stack may not be provided across an entire top surface of the core 201. In some instances, the TFC stack may be electrically coupled to one or more of the TGVs 205. After the TFC stack is patterned, standard package substrate manufacturing processes may be implemented in order to provide buildup layers, routing, and the like above and below the core 201. The routing may electrically couple the TFC stack to a die (not shown) over the package substrate 200.

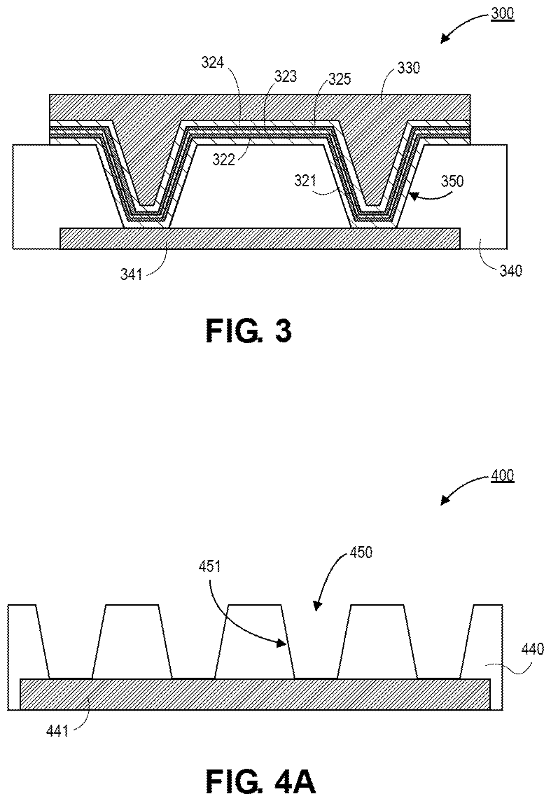

Referring now to FIG. 3, a cross-sectional illustration of a package substrate 300 at a stage of manufacture is shown, in accordance with an embodiment. In the illustrated embodiment, a buildup layer 340 is provided. The buildup layer 340 may be provided over a core (not shown) such as a glass core. In an embodiment, a pad 341 may be provided at the bottom of the buildup layer 340. A corrugated TFC may be provided within the buildup layer 340. For example, a pair of cavities 350 are provided in the buildup layer 340. A TFC may line the cavities 350 and pass over a top surface of the buildup layer 340.

In an embodiment, the TFC may comprise a first layer 321. The first layer 321 may comprise a seed layer and a bulk conductive layer, such as copper. The TFC stack may be provided over the first layer 321. The TFC stack comprises a first workfunction layer 322, a dielectric layer 323, and a second workfunction layer 324. The workfunction layers 322 and 324 may be substantially similar to the workfunction layers 222 and 224 described in greater detail above. Similarly, the dielectric layer 323 may be substantially similar to the dielectric layer 223 described in greater detail above. For example, the dielectric layer 323 may comprise a high-k dielectric material with a thickness between approximately 1 nm and approximately 100 nm. Since the TFC stack is lining the cavity 350, it may have a U-shaped cross-section in some embodiments. Additionally, U-shaped portions may be connected to each other by horizontal portions that are provided across a top surface of the buildup layer 340.

In an embodiment, a second layer 325 and a third layer 330 may be provided over the TFC stack. The second layer 325 may comprise a seed layer and a bulk conductive material, such as copper. The third layer 330 may comprise copper or the like. In some embodiments the third layer 330 and the second layer 325 may have a seamless interface, and the two layers 330 and 325 may appear as a single layer. The TFC stack, the first layer 321, the second layer 325, and the third layer 330 may be patterned so that some portions of the top surface of the buildup layer 340 are exposed. Additional buildup layers (not shown) may then be formed over the buildup layer 340 using standard semiconductor packaging assembly operations.

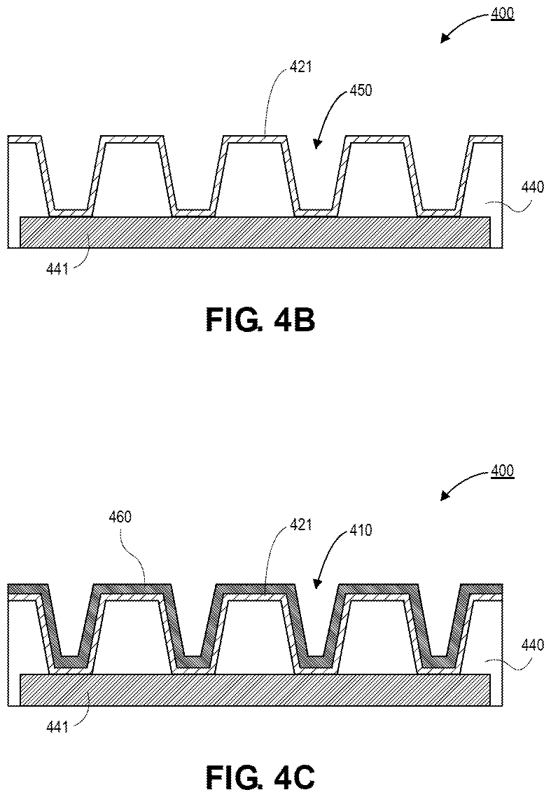

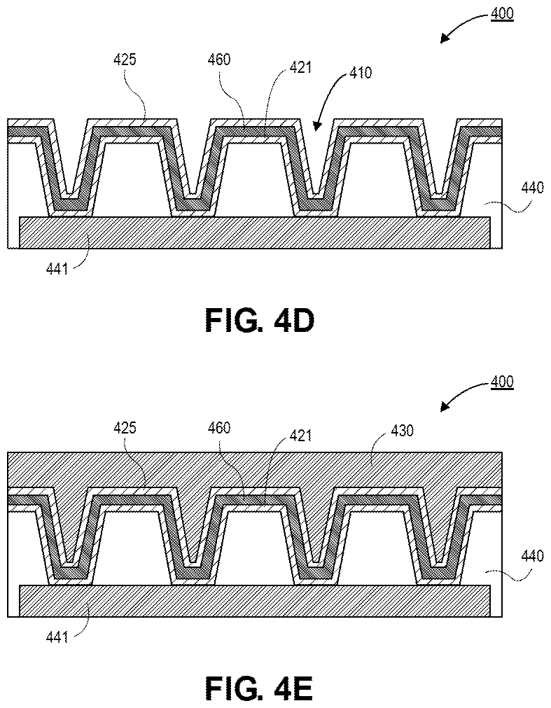

Referring now to FIGS. 4A-4E, a series of cross-sectional illustrations depicting a process for forming a TFC in a buildup layer 440 is shown, in accordance with an embodiment. The buildup layer 440 may be provided over a core (not shown), such as a glass core. In an embodiment, the TFC may be described as having a corrugated shape since portions multiple cavities into the buildup layer 440 are linked together.

Referring now to FIG. 4A, a cross-sectional illustration of a package substrate 400 at a stage of manufacture is shown, in accordance with an embodiment. In an embodiment, the package substrate 400 may comprise a buildup layer 440. The buildup layer 440 may be a dielectric material, such as a buildup film. In an embodiment, a pad 441 may be provided at the bottom of the buildup layer 440. In an embodiment, a series of cavities 450 may be formed into the buildup layer 440. The cavities 450 may extend through the buildup layer 440 and expose a top surface of the pad 441. While four cavities 450 are shown, it is to be appreciated that any number of cavities 450 may be provided into the buildup layer 440. In an embodiment, the cavities 450 may have sloped sidewalls 451. Though, in other embodiments, the sidewalls 451 may be substantially vertical.

Referring now to FIG. 4B, a cross-sectional illustration of the package substrate 400 after a first layer 421 is deposited over the buildup layer 440 and into the cavities 450 is shown, in accordance with an embodiment. The first layer 421 may comprise a seed layer and a bulk conductive material, such as copper. The first layer 421 may be substantially conformal to the surfaces of the buildup layer 440. That is, the first layer 421 may have a plurality of U-shaped regions that are connected to each other by horizontal regions across the top of the buildup layer 440.

Referring now to FIG. 4C, a cross-sectional illustration of the package substrate 400 after a TFC stack 460 is formed over the first layer 421 is shown, in accordance with an embodiment. The TFC stack 460 is shown as a single layer for simplicity. However, it is to be appreciated that the TFC stack 460 may comprise a first workfunction layer, a high-k dielectric layer, and a second workfunction layer. The high-k dielectric layer may have a thickness that is between approximately 1 nm and approximately 100 nm. The workfunction layers and the high-k dielectric may be similar to workfunction layers and high-k dielectric layers described in greater detail above. In an embodiment, the TFC stack 460 may be deposited with an ALD process.

Referring now to FIG. 4D, a cross-sectional illustration of the package substrate 400 after a second layer 425 is formed is shown, in accordance with an embodiment. In an embodiment, the second layer 425 may comprise a seed layer and a bulk metal layer, such as copper. In an embodiment, the second layer 425 may be deposited with any suitable deposition process. For example, an electroplating process may be used in some embodiments.

Referring now to FIG. 4E, a cross-sectional illustration of the package substrate 400 after a third layer 430 is provided over the second layer 425 is shown, in accordance with an embodiment. In an embodiment, the third layer 430 may be a bulk metal layer, such as copper. In an embodiment, the second layer 425 and the third layer 430 may be the same material. In such instances, there may not be a visible seam between the second layer 425 and the third layer 430. After the third layer 430 is formed, patterning may be done to expose portions of the buildup layer 440. Subsequent buildup layers may then be provided over the third layer 430.

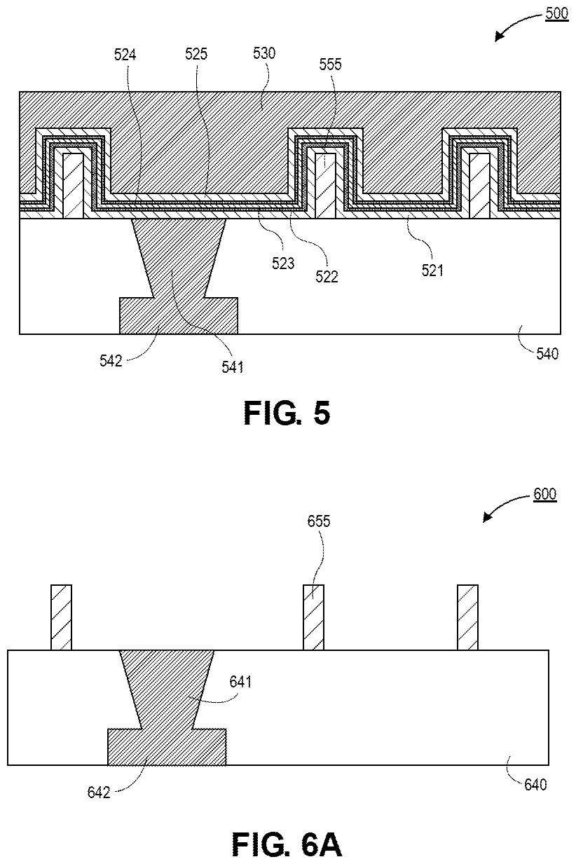

Referring now to FIG. 5, a cross-sectional illustration of a package substrate 500 at a stage of manufacture is shown, in accordance with an embodiment. The package substrate 500 may comprise a buildup layer 540, such as a buildup film. Vias 541 and pads 542 may be provided in the buildup layer 540. In an embodiment, a TFC may be provided over the buildup layer 540. Further, to increase the capacitance density, scaffolding 555 may be provided over the buildup layer 540. The scaffolding 555 may be formed with a photoimageable dielectric (PID) or the like. In an embodiment, the TFC may extend up sidewalls of the scaffolding 555 and over a top surface of the scaffolding 555.

In an embodiment, the TFC may comprise a first layer 521. The first layer 521 may comprise a seed layer and a bulk metal, such as copper. A TFC stack may then be provided over the first layer 521. The TFC stack may comprise a first workfunction layer 522, a high-k dielectric layer 523, and a second workfunction layer 524. A second layer 525 may be provided over the second workfunction layer 524. The second layer 525 may comprise a seed layer and a bulk metal layer, such as copper. A third layer 530 may be provided over the second layer 525.

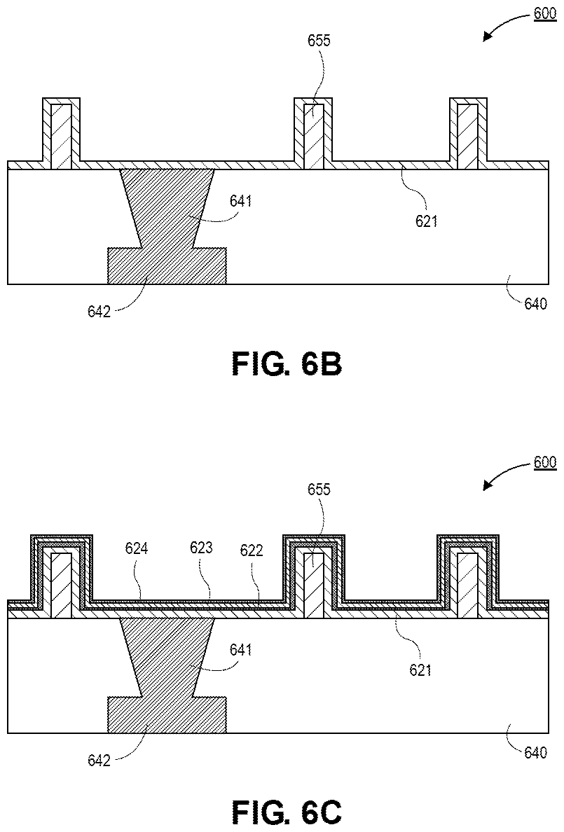

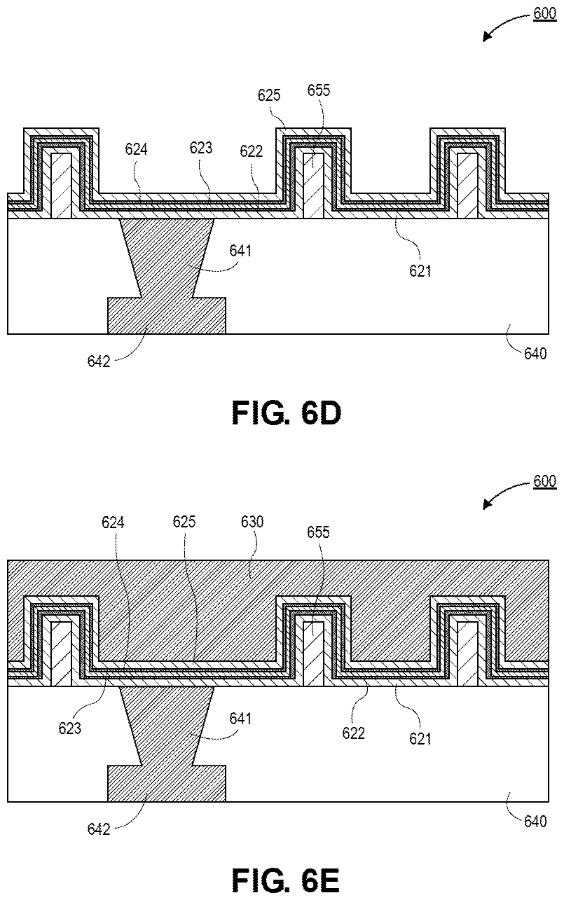

Referring now to FIGS. 6A-6E, a series of cross-sectional illustrations depicting a process for forming a package substrate 600 with a TFC is shown, in accordance with an embodiment.

Referring now to FIG. 6A, a cross-sectional illustration of a package substrate 600 at a stage of manufacture is shown, in accordance with an embodiment. The package substrate 600 may comprise a buildup layer 640. The buildup layer 640 may be provided over a core (not shown) such as a glass core. In an embodiment, conductive routing (e.g., via 641 and pad 642) may be provided in the buildup layer 640.

In an embodiment, scaffolding 655 may be provided over a top surface of the buildup layer 640. In an embodiment, the scaffolding 655 may comprise a PID. The PID may be deposited, exposed with electromagnetic radiation, and developed. The scaffolding 655 may comprise any number of spines that extend up from the buildup layer 640.

Referring now to FIG. 6B, a cross-sectional illustration of the package substrate 600 after a first layer 621 is disposed over the buildup layer 640 and the scaffolding 655 is shown, in accordance with an embodiment. The first layer 621 may comprise a seed layer and a bulk metal layer. The bulk metal layer may comprise copper or the like. In an embodiment, the bulk metal may be deposited with an electroplating process.

Referring now to FIG. 6C, a cross-sectional illustration of the package substrate 600 after a TFC stack is deposited over the first layer 621 is shown, in accordance with an embodiment. In an embodiment, the TFC stack comprises a first workfunction layer 622, a high-k dielectric layer 623, and a second workfunction layer 624. In an embodiment, the TFC stack may be similar to other TFC stacks described in greater detail above. The TFC stack may be formed with ALD processes.

Referring now to FIG. 6D, a cross-sectional illustration of the package substrate 600 after a second layer 625 is formed is shown, in accordance with an embodiment. In an embodiment, the second layer 625 may comprise a seed layer and a bulk metal layer, such as copper. In an embodiment, the second layer 625 may be deposited with any suitable deposition process. For example, an electroplating process may be used in some embodiments.

Referring now to FIG. 6E, a cross-sectional illustration of the package substrate 600 after a third layer 630 is provided over the second layer 625 is shown, in accordance with an embodiment. In an embodiment, the third layer 630 may be a bulk metal layer, such as copper. In an embodiment, the second layer 625 and the third layer 630 may be the same material. In such instances, there may not be a visible seam between the second layer 625 and the third layer 630. After the third layer 630 is formed, patterning may be done to expose portions of the buildup layer 640. Subsequent buildup layers may then be provided over the third layer 630.

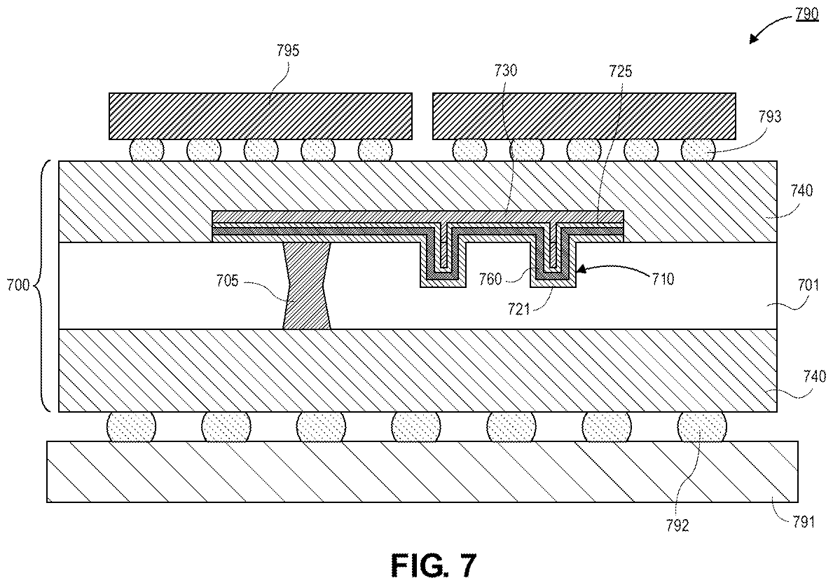

Referring now to FIG. 7, a cross-sectional illustration of an electronic system 790 is shown, in accordance with an embodiment. The electronic system 790 may comprise a board 791, such as a printed circuit board (PCB). The PCB 791 may be coupled to a package substrate 700 by interconnects 792. While shown as solder balls, it is to be appreciated that any interconnect 792 architecture may be used, such as sockets or the like.

In an embodiment, the package substrate 700 may comprise a core 701, such as a glass core 701. Buildup layers 740 may be provided above and below the core 701. In an embodiment, a TGV 705 may pass through a thickness of the core 701. In an embodiment, a TFC structure may be provided over and in the core 701. The TFC structure may include a first layer 721, a TFC stack 760, and a second layer 725. A third layer 730 may be provided over the second layer 725. In an embodiment, the TFC stack 760 may comprise a first workfunction layer, a high-k dielectric layers, and a second workfunction layer. The TFC stack may be similar to any of the TFC stacks described in greater detail above. In an embodiment, the TFC structure shown in FIG. 7 is similar to the TFC structure shown in FIG. 1. Though, it is to be appreciated that any of the TFC structures (e.g., FIG. 3 or FIG. 5) can be incorporated into the package substrate 700.

In an embodiment, one or more dies 795 may be coupled to the package substrate 700 by interconnects 793. The interconnects 793 may be any first level interconnect (FLI) architecture. In an embodiment, the dies 795 may be any suitable compute die, such as a central processing unit (CPU), a graphics processing unit (GPU), a system on a chip (SoC), an application specific integrated circuit (ASIC), a memory die, or any other type of die. In an embodiment, the TFC structure may be electrically coupled to one or more of the dies 795. The TFC structure may be used as part of the power delivery network for the one or more dies 795.

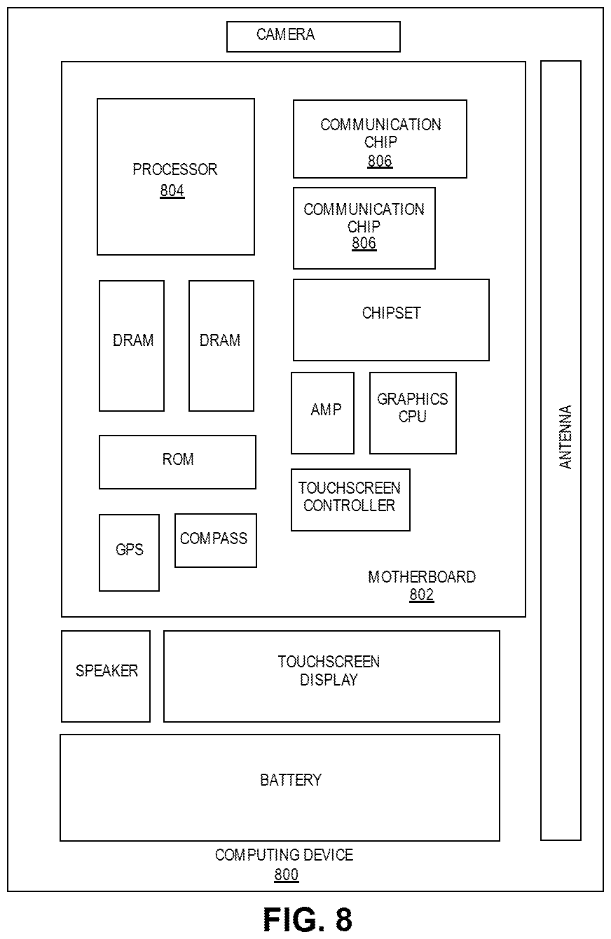

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a TFC structure that is embedded in a core or buildup layers of the package substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a TFC structure that is embedded in a core or buildup layers of the package substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package core, comprising: a core substrate comprising glass; a cavity into the core substrate; and a capacitor lining sidewalls of the cavity, wherein the capacitor comprises: a first layer; a dielectric layer over the first layer; and a second layer over the dielectric layer.

Example 2: the package core of Example 1, wherein the capacitor has a U-shaped cross-section.

Example 3: the package core of Example 1 or Example 2, wherein sidewalls of the cavity are vertical.

Example 4: the package core of Example 1 or Example 2, wherein sidewalls of the cavity are sloped.

Example 5: the package core of Examples 1-4, further comprising: a seed layer between the core substrate and the first layer.

Example 6: the package core of Examples 1-5, wherein the first layer and the second layer comprise ruthenium, ruthenium and oxygen, or tungsten.

Example 7: the package core of Examples 1-6, wherein the dielectric layer comprises titanium and oxygen, aluminum and oxygen, or hafnium and oxygen.

Example 8: the package core of Examples 1-7, further comprising: a via through the core substrate, wherein the via is electrically coupled to the capacitor.

Example 9: the package core of Example 8, wherein the via has an hourglass shaped cross-section.

Example 10: the package core of Examples 1-9, wherein the package core is part of a computing system for a personal computer, a server, a mobile device, a tablet, or an automobile.

Example 11: a package substrate, comprising: a core; a buildup layer over the core; and a corrugated capacitor within the buildup layer, wherein the corrugated capacitor comprises: a plurality of trenches into the core, wherein the trenches have sidewall surfaces; and a capacitor structure lining the sidewall surfaces of the plurality of trenches.

Example 12: the package substrate of Example 11, further comprising: an underlying pad, wherein the corrugated capacitor contacts the underlying pad at more than one location.

Example 13: the package substrate of Example 11 or Example 12, wherein the corrugated capacitor comprises a dielectric layer between a first layer and a second layer.

Example 14: the package substrate of Example 13, wherein the dielectric layer comprises titanium and oxygen, aluminum and oxygen, or hafnium and oxygen.

Example 15: the package substrate of Examples 11-14, wherein the plurality of trenches comprises three or more trenches.

Example 16: the package substrate of Examples 11-15, wherein the package substrate is part of a computing system for a personal computer, a server, a mobile device, a tablet, or an automobile.

Example 17: a package substrate, comprising: a layer comprising a dielectric; a scaffold over the layer; and a capacitor over the scaffold, wherein the capacitor comprises: a first layer; a dielectric layer over the first layer; and a second layer over the dielectric layer.

Example 18: the package substrate of Example 17, wherein the scaffold is a photoimageable dielectric (PID).

Example 19: the package substrate of Example 17 or Example 18, wherein the scaffold has substantially vertical sidewalls.

Example 20: the package substrate of Examples 17-19, wherein the package substrate is part of a computing system for a personal computer, a server, a mobile device, a tablet, or an automobile.

What is claimed is:

1. A package core, comprising:
a core substrate comprising glass;
a cavity into the core substrate; and
a capacitor lining sidewalls of the cavity, wherein the capacitor comprises:
a first layer;
a dielectric layer over the first layer; and
a second layer over the dielectric layer.

2. The package core of claim 1, wherein the capacitor has a U-shaped cross-section.

3. The package core of claim 1, wherein sidewalls of the cavity are vertical.

4. The package core of claim 1, wherein sidewalls of the cavity are sloped.

5. The package core of claim 1, further comprising:
a seed layer between the core substrate and the first layer.

6. The package core of claim 1, wherein the first layer and the second layer comprise ruthenium, ruthenium and oxygen, or tungsten.

7. The package core of claim 1, wherein the dielectric layer comprises titanium and oxygen, aluminum and oxygen, or hafnium and oxygen.

8. The package core of claim 1, further comprising:
a via through the core substrate, wherein the via is electrically coupled to the capacitor.

9. The package core of claim 8, wherein the via has an hourglass shaped cross-section.

10. The package core of claim 1, wherein the package core is part of a computing system for a personal computer, a server, a mobile device, a tablet, or an automobile.

11. A package substrate, comprising:
a core;
a buildup layer over the core; and
a corrugated capacitor within the buildup layer, wherein the corrugated capacitor comprises:
a plurality of trenches into the core, wherein the trenches have sidewall surfaces; and
a capacitor structure lining the sidewall surfaces of the plurality of trenches.

12. The package substrate of claim 11, further comprising:
an underlying pad, wherein the corrugated capacitor contacts the underlying pad at more than one location.

13. The package substrate of claim 11, wherein the corrugated capacitor comprises a dielectric layer between a first layer and a second layer.

14. The package substrate of claim 13, wherein the dielectric layer comprises titanium and oxygen, aluminum and oxygen, or hafnium and oxygen.

15. The package substrate of claim 11, wherein the plurality of trenches comprises three or more trenches.

16. The package substrate of claim 11, wherein the package substrate is part of a computing system for a personal computer, a server, a mobile device, a tablet, or an automobile.

17. A package substrate, comprising:
a layer comprising a dielectric;
a scaffold over the layer; and
a capacitor over the scaffold, wherein the capacitor comprises:
a first layer;
a dielectric layer over the first layer; and
a second layer over the dielectric layer.

18. The package substrate of claim 17, wherein the scaffold is a photoimageable dielectric (PID).

19. The package substrate of claim 17, wherein the scaffold has substantially vertical sidewalls.

20. The package substrate of claim 17, wherein the package substrate is part of a computing system for a personal computer, a server, a mobile device, a tablet, or an automobile.
